(19) United States
(12) Patent Application Publication
(10) Pub. No.: US 2006/0285404 A1
(43) Pub. Date: Dec. 21, 2006

(54) Multi-use strobe and illumination module

(76) Inventor: Allen K. Alexander, Spring, TX (US)

Correspondence Address: CENTRAL COAST PATENT AGENCY, INC, 3 HANGAR WAY SUITE D, WATSONVILLE, CA, 95076, US

(21) Appl. No.: 11/437,071

(22) Filed: May 19, 2006

Related U.S. Application Data
(60) Provisional application No. 60/682,656, filed on May 19, 2005.

(51) Int. Cl. G11C 29/00; G11C 7/00

(52) U.S. Cl. 365/200

(57) ABSTRACT

A system for illuminating and signaling in a hands free manner includes an illumination module comprising at least one independent light source and strobe emitter, and a material holder for supporting the illumination module for hands free use.

### CROSS-REFERENCE TO RELATED APPLICATIONS

The present invention claims priority to a U.S. provisional patent application entitled HANDS-FREE MULTI-FUNCTIONAL UTILITY ILLUMINATING DEVICE Ser. No. 60/682,656 filed on May 20, 2005 and said application is incorporated herein at least by rerefence.

### BACKGROUND OF THE INVENTION

1. Field of the Invention

The present invention pertains to illuminating devices, and more particularly to a hands-free multi-functional utility illuminating apparatus adapted to be worn in different locations, such as about the wrist of a user, and having a variety of light-emitting devices, such as a diode and strobe light emitter.

2. Discussion of the State of the Art

Whether for use in law enforcement or military, or by ordinary citizens, lighting devices, such as flashlights, are used to illuminate dark areas. However, the flashlight, while an adequate light source, occupies the hands and limits a person's ability to use both hands. Furthermore, the flashlight does not emit a strobe or other visual indicator that would be eye-catching for locating a person in distress in a variety of ambient lighting conditions.

In view of the above, there is a continuing need for a hands-free multi-functional utility illuminating module adapted to be worn about the wrist of a user or on a belt or vest worn by a user and having at least one light emitting diode and a separate strobe emitter.

As will be seen more fully below, the present invention is substantially different in structure, methodology and approach from that of other light sources.

### SUMMARY OF THE INVENTION

According to an aspect of the invention, a system is provided for illuminating in a hands free manner. The system includes an illumination module including at least one independent light source and strobe emitter, and a material holder for supporting the illumination module for hands free use. In a preferred embodiment, the illumination module is secured to the holder using hook and loop connectors. In one embodiment, the at least one independent light source is a light emitting diode (LED). In a preferred embodiment, there is more than one LED each emitting a different color of light.

In one embodiment, the material holder is one of a wristband, a legband, or an armband. In one embodiment, the material holder is a material pocket having at least one flap to secure the module inside the pocket. In a variation of this embodiment, the material holder has an extension for looping around a belt. In another variation of the embodiment, the material holder has a belt loop or a belt clip attached thereto for securing to a belt.

According to another aspect of the invention, an illumination module is provided. The illumination module includes two or more LEDs each LED emitting a different color of light, a strobe emitter for producing a sequence of strobe flashes, and an input panel of buttons for activating and controlling the LEDs and the strobe emitter. In a preferred embodiment, there is one white LED and one red LED, the LEDs independently operable from the input panel. In a variation of this embodiment, the strobe emitter is a bulb.

In one embodiment, the illumination module further includes a magnetic strip for magnetic attachment to a metallic surface. In one embodiment, the illumination module further includes modular covers over the LEDs and the strobe emitter, the covers exchangeable for like covers of varying transparencies and light directing features. In a variation of this embodiment, the light direction features are transparent windows on otherwise non-transparent covers. In one embodiment, the LEDs are independently adjustable for direction of light emission.

According to a variation of the first embodiment of the invention, the material holder of the system includes a vest band. In a further variation of this embodiment, the material holder includes an animal collar. In one aspect of this embodiment, the animal collar is a dog collar.

### BRIEF DESCRIPTION OF THE DRAWING FIGURES

FIG. 1 is a perspective view of a hands free light and strobe emitting system according to an embodiment of the present invention.

FIG. 2A is a front view of the light and strobe emitting module of FIG. 1.

FIG. 2B is a top view of the light and strobe emitting module of FIG. 2A.

FIG. 3A is a top view of the light and strobe emitting module supported by a material holder according to another embodiment of the present invention.

FIG. 3B is a side view of the module and holder of FIG. 3A.

FIG. 4 is a block diagram illustrating the basic components of the light and strobe-emitting module of FIG. 1 according to an embodiment of the present invention.

FIG. 5 is a perspective view of a light and strobe emitting module and a holder according to another embodiment of the invention.

FIG. 6 is an elevation view of a version of the module of FIG. 1 supported on a dog collar according to an embodiment of the invention.

FIG. 7 is an elevation view of the module of FIG. 1 supported on a vest band and a belt.

### DETAILED DESCRIPTION OF THE INVENTION

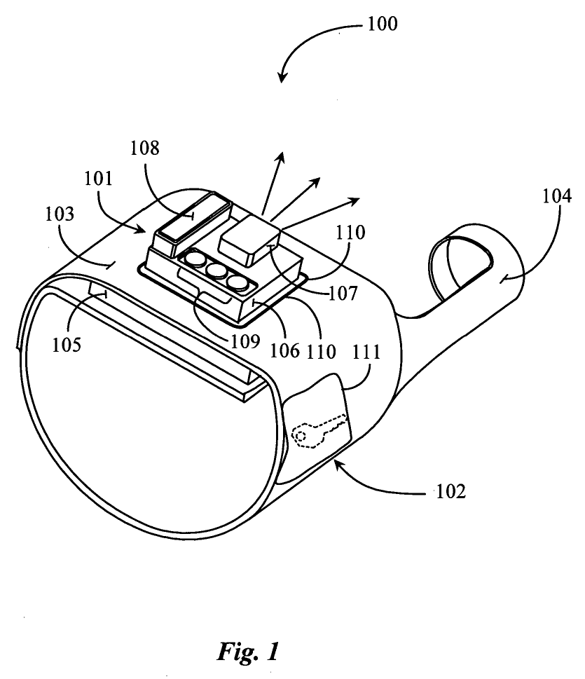

FIG. 1 is a perspective view of a hands free light and strobe emitting system 100 according to an embodiment of the present invention. System 100 includes a light source and strobe-emitting module 101. Module 101 is an electronics module and houses electronic circuitry and a power source. Module 101 has a base portion 105 generally rectangular in shape in this example. Base 105 may have one or more compartments (not illustrated) for housing batteries, power cells, or the like for powering the module. In one embodiment, the power source may be one or more AAA batteries. However, other power sources and batteries types, including re-chargeable batteries or cells may be used.

Module 101 has an upper body portion 106 provided to house electronic circuitry required to enable function of the module according to embodiments of the invention. Body 106 is rectangular in shape in this embodiment and is situated above and centered over base 105. Base 105 and body 106 may be contiguously formed of molded plastic like ABS plastic, for example. Base 105 may have an access door provided on its underside (not visible) for enabling access to batteries or power cells.

Upper body portion 106 has a user interface panel of buttons or switches 109 for activating and controlling the functions of module 101. The functions of module 101 include acting as an illumination module capable of producing a bright white light and an illumination module capable of producing a bright red light, such as in the infra-red spectrum. The illumination devices are light emitting diodes (LEDs) in a preferred embodiment. The diodes are housed within an LED compartment having a removable cover 107 situated strategically on top of upper body 106. In this example, light is emitted in the general forward direction indicated by arrows. Module 101 comprises in this embodiment a strobe light that is capable of emitting a sequence of timed flashes of high intensity bright light. The strobe light is housed in this embodiment within a strobe compartment having a removable cover 108. Strobe cover 108 may, in one embodiment, be transparent so that emitted flashes of bright light emanate through the cover. In another embodiment, strobe cover 108 may have a transparent opening in one end for focusing strobe flashes in one general direction.

A user interacting with one or more buttons or switches 109 controls module 101. xxxxx For example, one button may control a bright white LED while another controls a red LED and the third button controls the strobe. In one example, depressing one button powers the associated LED or strobe on and pressing it a second time turn it off. In a preferred embodiment, the strobe flashes once every 0.75 seconds. However, other timing considerations may be implemented. Additionally, more than one timing sequence may be provided and implemented such as by repeatedly depressing the button 109 associated to the strobe function.

The functions of module 101 or more specifically, the LEDs and the strobe bulb communicate with the appropriate printed circuits housed in upper body 106 and with the battery compartment via appropriate power and signal trace. The amount of intelligence built into module 101 depends on the circuitry provided to drive the utilities.

System 100 includes a material arm or wrist support 102 for holding module 101 in a position that is stable for hands free operation. Wrist support 102 may be fabricated from a stiff or pliable material that may be wrapped around the arm or wrist of a user. Cordura, leather, canvas, or other materials may be used in fabricating wrist support 102. Support 102 includes a portion 103 that fits over module 101 and secures it between the overlapping layers of wrist support 102 by way of a cutout 110 provided through the overlap portion 103. Cutout 110 is rectangular in shape and is just large enough dimensionally to fit snuggly over upper body portion 106 of module 101.

Wrist support 102 may be secured around the wrist of a user by hook and loop connection typical of wrap around belts and bands. With module 101 in position, portion 103 of wrist support 102 is urged down over the module against the upper surface of base 105 exposing the interface and body potion 106 through cutout 110. The hook and loop connection is then secured to firmly hold module 101 in position on the wrist or arm of a user. Wrist support 102 has a material extension 104 having a loop formed at the free end for wrapping around a finger of a user to prevent wrist support 102 from slipping around the wrist of a user while being worn. The loop formed at the end of material extension 104 may be a solid loop or ring sized generally to fit a ring finger or little finger of the user. In one embodiment the finger loop is physically wrapped around a finger and secured using a hook and loop connection similar to the one used on support 102.

The configuration of system 100 in this example enables a user to handle a weapon like a firearm, for example, with both hands remaining free to hold and brace the weapon for firing in traditional stance used by law enforcement and to have a high intensity light shining in the same direction as the weapon is being pointed. Persons engaging tools in dark areas such as underneath an automobile when performing repairs may use system 100 as a hands free light source. The direction of the light emitted from the LEDs of module 101 when powered on coincides generally with the angle at which the light is desired to illuminate the work area without having to hold and point a flashlight or other handheld light source.

Wrist support 102 may vary in design somewhat without departing from the spirit and scope of the present invention. For example, there may be a three sided rectangular pocket formed on the upper surface of overlap portion 103 wherein the pocket accepts module 101 by sliding the module into the pocket. In this case, the upper body portion may still be exposed through a cutout in the top of the pocket and a separate flap may be provided to secure module 101 within the pocket by hook and loop connection. There are many possibilities. In this example, system 100 is intended to be worn on a user's wrist and to be stabilized on the wrist via material extension 104. However, similar designs without finger stabilizers may be provided for the upper arm of a user in some cases. For example, an emergency worker stacking sand bags at night to prevent flooding might wear an armband with module 101 instead of a wristband with module 101 in order to have a more general illumination area. Likewise, it is conceivable that a support like 102 may be provided for wrapping around the leg of a user. There are many possibilities.

In addition to the LED function, the strobe emitter may be activated on module 101 to produce a sequence of high intensity flashes that are visible from a relatively great distance. This is practical for search and rescue missions where the target of the search has system 100 and activates it to facilitate spotting during the search. The activated strobe can be spotted from a distance at night, underwater, under rubble, under snow, and in a variety of other rescue situations. In one embodiment, all of the utilities may be activated to run separately from one another or at the same time. Each utility has it's own circuitry in a preferred embodiment.

The red LED may be used in situations where some light is required but not enough that might attract attention. Undercover work, soldering, and the like are good situations where one may require some light but not intense brightness. Reading maps at night is a good example of such a use. Another is preparing demolitions under cover of darkness in a battle situation. There are many possibilities.

In one embodiment, the LEDs of module 101 may be set at differing levels of brightness of emission by toggling the associated buttons 109. Likewise, the strobe emitter may be set to flash at a slower frequency or a faster frequency depending on need. In one embodiment wrist support 102 has a sewn pocket 111 for inserting therein a key or other small item.

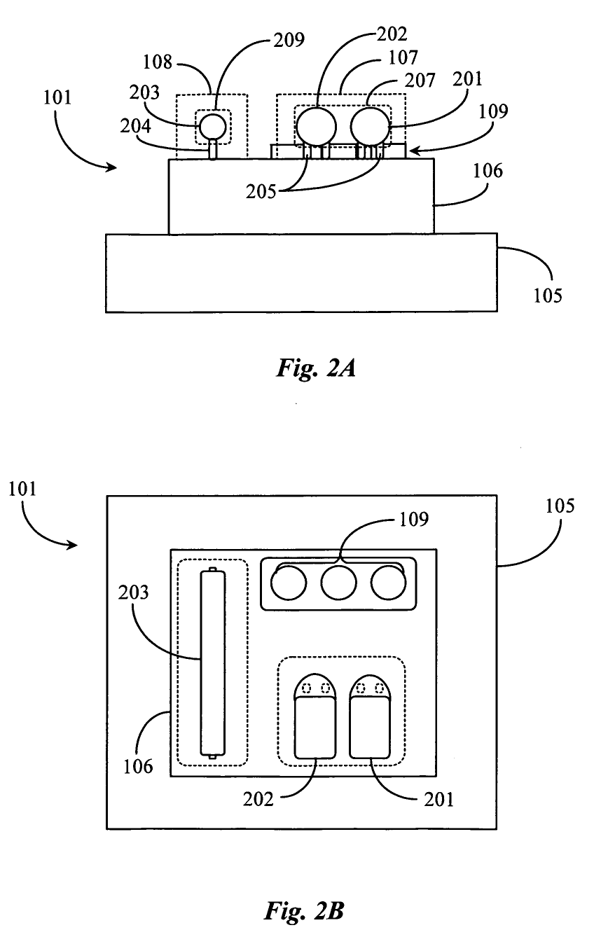

FIG. 2A is a front view of the light and strobe emitting module 101 of FIG. 1.

FIG. 2B is a top view of the light and strobe emitting module 101 of FIG. 2A.

Referring now to FIG. 2A, module 101 includes base 105 for housing batteries and serving as a flange for installing the module in a band as was previously described. Upper body 106 houses the driver circuitry enabling function of the module. Strobe bulb cover 108 and LED compartment cover 107 are removed in this example for clarity. In this view, an LED 201 and an LED 202 are mounted and directed to emit light in a uniform direction. Cover 107 may have a transparent window 207 through which light is emitted. The bottom of the LED compartment has openings provided to enable electrical communication traces 205 to connect the LEDs to a printed circuit board (PCB) mounted within upper body 106. The circuit board, not visible in this example contains all of the required circuitry to enable the functions and features of the invention. In one embodiment, more than one circuit board may be provided.

Button panel 109 is located behind the LED compartment in this view and also has connection to appropriate gates on the PCB enabling activation and control of the utilities individually and in unison if desired. A strobe bulb 203 is provided in this example and has electrical communication to the PCB and associated circuitry via electrical communication paths 204. Cover 108 may have a window 209 for directing strobe flashes. Cover 108 may also be transparent to expand visibility of the strobe. More than one cover may be provided for setting up different scenarios depending on circumstance. For example, if using the strobe as a rescue beacon then the transparent cover would be used. If using the strobe as a signaling device, then a non-transparent cover with a transparent window would be used.

Referring now to FIG. 2B, the geometric arrangement of LED 201, LED 202, strobe bulb 203, and input panel 109 may vary significantly without departing from the spirit and scope of the present invention. In this example, LEDs 201 and 202 have back shielding and are constructed to focus light in one direction. LEDs 201 and 202 are fixed adjacently in this example. In one embodiment, LEDs 201 and 202 may be adjusted at the mounted positions to align or to change direction of light emission.

One with skill in the art of plastic molding will appreciate the use of the present invention does not depend on geometric shape of module 101. Instead of rectangular shapes for base 105 and upper body portion 106, elliptical or annular shapes may be incorporated into the design. Similarly for a rectangular configuration, corners and edges may be rounded or chamfered.

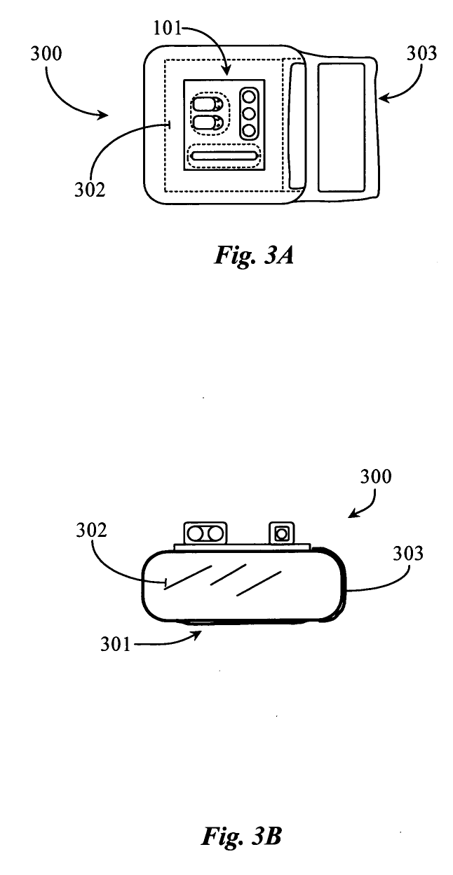

FIG. 3A is a top view of the light and strobe emitting module 101 of FIG. 1 supported by a material holder 300 according to another embodiment of the present invention. Material holder 300 may be provided of a durable cloth like cordura, or nylon 302. Some other material like leather or canvas may also be used instead. In this example, holder 300 is sewn forming a rectangular pocket having three sewn walls, a cutout window to accommodate upper body portion 106 and a closeable flap 303 to form the fourth side. A hook and loop connection on the inner side of flap 303 and on the upper right surface of holder 300 in this view enable a user to secure module 101 within the holder.

Module 101 may be placed into pocket 300 by sliding the module in through the open end with flap 300 in an open position. When module 101 is secured in holder 300 with the window properly formed around the upper body portion of the module, flap 300 may be closed and secured using the hook and loop connection provided.

FIG. 3B is a side view of module 101 and holder 300 of FIG. 3A. In this view, material holder 300 has module 101 secured with flap 303 closed. Module 101 is entirely covered accept for the exposes utilities (LEDs, strobe bulb, and input panel). A belt loop 301 may be provided and sewn on to the underside of material holder 300 so that a user may install module 101 on a belt. In one embodiment, a hook or loop pad may be provided on the underside of holder 300 so that a user may secure holder 300 with module 101 inside to a hook or loop pad provided on a wristband or other band, or on some article of clothing such as a hunting jacket or the like. Industrial strength hook and loop materials may provide a secure one-stick installation without requiring an overlay flap or any other attachment mechanisms.

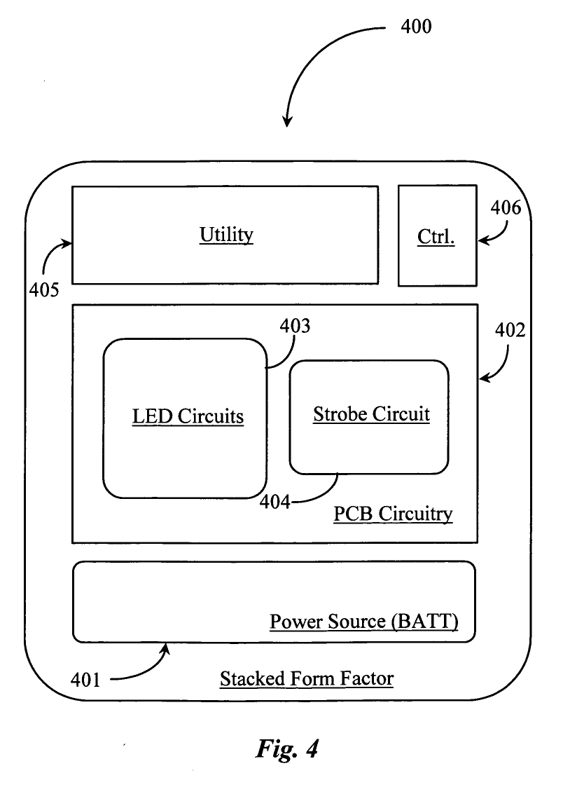

FIG. 4 is a block diagram illustrating the basic components 400 of the light and strobe-emitting module of FIG. 1 according to an embodiment of the present invention. The block diagram illustrating components 400 is a logical diagram only and does not strictly follow any geometric arrangements of components. Components 400 include a utility 405 that includes the LEDs and the strobe bulb or emitter described further above. A control (Ctrl,) block 406 includes the user input panel of buttons for activating and controlling functions and features of the module.

A block 402 illustrated PCB circuitry containing all of the necessary circuitry to operate and control the module. PCB circuitry 402 contains at least LED circuits 403 and a strobe circuit 404. A power source block 401 includes the battery or power cell compartment and terminals connected to the PCB board to provide power to the module. In a preferred embodiment, module 101 uses a stacked form factor to lower the footprint of the module. The batteries are provided in the first level, the PCB circuitry at the second level, and the utilities and control buttons at the top level as illustrated in the previous embodiments.

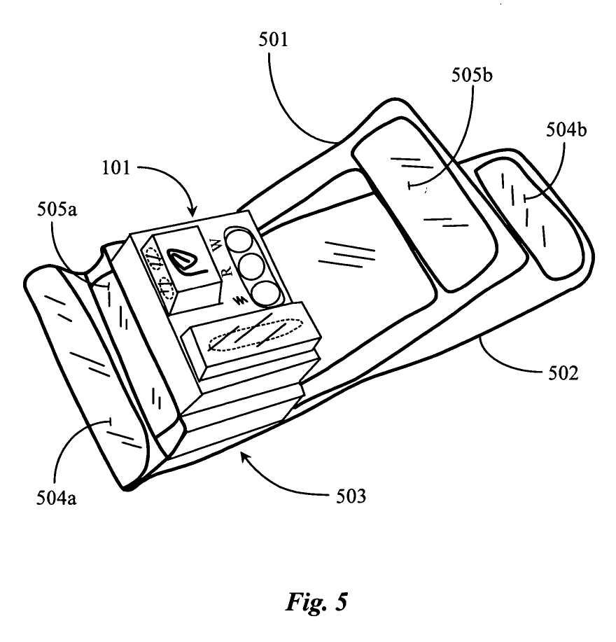

FIG. 5 is a perspective view of light and strobe emitting module 101 and a material holder 503 according to another embodiment of the invention. In this example, a material holder 503 is provided to contain and secure module 101. Material holder 503 has 3 sewn sidewalls and an open side for accepting the module. Holder 503 has a locking flap 501 with a window cutout dimensioned to fit over the upper body portion of module 101. Locking flap 501 has a hook or loop provided on the undersurface. The material sidewall opposite the free end of flap 501 has a hook or loop connector 505a provided on the outer surface. In this example, locking flap 501 is placed over module 101 in the pocket and is secured by connection of the hook and loop connectors 505a and 505b.

Material holder 503 has an outer extension 502 that can be used to secure the module from a belt or waistband, or some other support band using hook and loop connectors 504a and 504b. In this embodiment, while module 101 is being worn on a belt or being supported on a wrist band or the like, the user may easily remove dive 101 and replace it by un-securing flap 501 and sliding the module out from the pocket of holder 503. In this way, the module may be moved from belt to wrist to vest, for example, when desired.

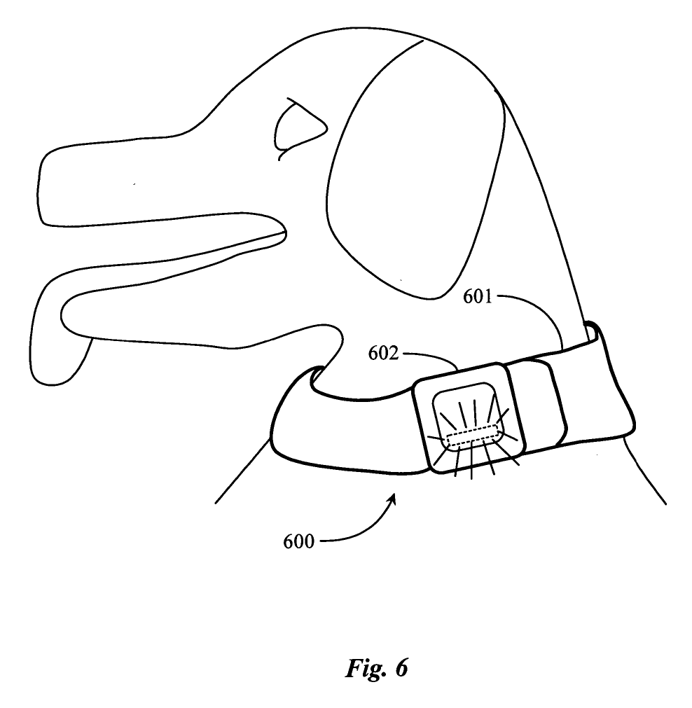

FIG. 6 is an elevation view of a version of the module of FIG. 1 supported on a dog collar according to an embodiment of the invention. In one embodiment of the present invention module 101 or a version of module 101 may be provided to a dog collar using the same material holder design described above. A dog 600 with a dog collar 601 has material holder 602 and a version of module 101 containing at least the strobe function. In this example, LEDs may not be desired. Rather, the dog may need to be found if lost during some operation or as a result of general circumstance. The strobe bulb of system 602 may be activated by remote, perhaps by a remote control device provided for the purpose. In one embodiment a telephone communications device like a cell phone may activate the bulb. In any case, activation of the strobe emitter on the dog collar causes intense strobe flashing to occur that is visible from a great distance (up to 4 miles) even in low visibility conditions like fog. Hunting dogs might use the collars so that their owner may quickly sight the dogs from a distance as they are working. Cattle herding dogs may also use the collar to provide an additional incentive (intense strobe flashing) for cattle or other herded animals to submit to the dog. There are many possibilities.

FIG. 7 is an elevation view of module 101 of FIG. 1 supported on a vest band and a belt. A vest 700 is illustrated having a vest cross-band 701 and a belt 702. Vest 700 may be any type of clothing, but a vest is illustrated because of the existence of many types of uniform safety vests worn by various road crew, emergency personnel, rescue workers, miners, law enforcement, firemen and the like. Module 101 using a material holder like those already described may be attached securely to a vest band 701 or a belt 702 as is illustrated. Using the high intensity strobe feature on a vest provides an added safety factor for road crews and the like to increase their visibility to passing motorists. Likewise, firemen or miners may use them so that they may quickly locate one another in low visibility condition such as in a smoke-filled house or underground in a dust filled mine. Children at play or joggers and bike riders may also wear the module of the present invention for safety purposes to increase their visibility to others.

In one embodiment of the present invention module 101 of FIG. 1 may include a magnet glued to the rear battery cover so that the module may stuck on to a metal surface such as a refrigerator. Likewise, the material holder may also have a magnetic strip on the bottom side for magnetically attaching the module to a metal surface. The possible applications are virtually endless. The module of the present invention when supported by a wristband as shown in FIG. 1 may be positioned on the upper or lower side of the wrist of a user, or on either side of the wrist of a user without departing from the spirit and scope of the present invention. The module of the present invention may be provided using all of or some of the components described without departing from the spirit and scope of the present invention. For example, there may be more than two LEDs and/or more than one strobe emitter provided on a single module.

There may be fewer or more than three input buttons for activating and controlling the module. Specific versions of the module may also be provided wherein the features are dedicated to specific uses. For example, if used on a dog collar, the LED features of the module may not be applicable. Therefore the module may be provided with only the strobe feature without departing from the spirit and scope of the invention. Likewise, for a mechanic, a module may be provided without the strobe feature because it may not be required for hands free illumination of a work area.

The spirit and scope of the present invention should only be limited by the following claims.

What is claimed is:

1. A system for illuminating in a hands free manner comprising:
an illumination module including at least one independent light source and strobe emitter; and
a material holder for supporting the illumination device for hands free use.

2. The system of claim 1, wherein the illumination device is secured to the holder using hook and loop connectors.

3. The system of claim 1, wherein the at least one independent light source is a light emitting diode (LED).

4. The system of claim 3, wherein there is more than one LED each emitting a different color of light.

5. The system of claim 1, wherein the material holder is one of a wristband, a legband, or an armband.

6. The system of claim 1, wherein the material holder is a material pocket having at least one flap to secure the module inside the pocket.

7. The system of claim 6, wherein the material holder has an extension for looping around a belt.

8. The system of claim 6, wherein the material holder has a belt loop or a belt clip attached thereto for securing to a belt.

9. An illumination module comprising:
two or more LEDs each LED emitting a different color of light;
a strobe emitter for producing a sequence of strobe flashes; and
an input panel of buttons for activating and controlling the LEDs and the strobe emitter.

10. The illumination module of claim 9, wherein there is one white LED and one red LED, the LEDs independently operable from the input panel.

11. The illumination module of claim 9, wherein the strobe emitter is a bulb.

12. The illumination module of claim 9 further including a magnetic strip for magnetic attachment to a metallic surface.

13. The illumination module of claim 9, having modular covers over the LEDs and the strobe emitter, the covers exchangeable for like covers of varying transparencies and light directing features.

14. The illumination module of claim 13, wherein the light direction features are transparent windows on otherwise non-transparent covers.

15. The illumination module of claim 13, wherein the LEDs are independently adjustable for direction of light emission.

16. The system of claim 1, wherein the material holder includes a vest band.

17. The system of claim 1, wherein the material holder includes an animal collar.

18. The system of claim 17, wherein the animal collar is a dog collar.
